(19) United States
(12) Patent Application Publication
(10) Pub. No.: US 2024/0030232 A1
(43) Pub. Date: Jan. 25, 2024

(54) DISPLAY PANEL AND DISPLAY DEVICE

(71) Applicant: WUHAN CHINA STAR OPTOELECTRONICS TECHNOLOGY CO., LTD., Wuhan (CN)

(72) Inventors: Yuan SUN, Wuhan (CN); Chao WANG, Wuhan (CN); Guanghui LIU, Wuhan (CN); Liwang LIU, Wuhan (CN)

(21) Appl. No.: 17/623,214

(22) PCT Filed: Dec. 9, 2021
(86) PCT No.: PCT/CN2021/136840

§ 371 Date: Dec. 27, 2021

(30) Foreign Application Priority Data
Dec. 2, 2021 (CN) 202111460214.3

(51) Int. Cl. H01L 27/12

(52) U.S. Cl. CPC H01L 27/124

(57) ABSTRACT

The present application discloses a display panel and a display device. The display panel includes an active layer, a gate layer, and a metal layer, which is able to quickly pull down a falling edge of a scan signal in a first scan line when a rising edge of a scan signal in a second scan line arrives. By constructing a low-potential wiring, a control wiring, and a pull-down transistor between the first data line and the second data line, a layout with less space can be completed and an aperture ratio can be increased as much as possible.

### FIELD OF INVENTION

The present application relates to a display technology field, and particularly to a display panel and a display device.

### BACKGROUND

With the development of display technology, a refresh frequency has become one of the important indications for measuring display effects. Screens with high refresh frequency can bring a smoother visual experience and reduce fatigue of human eyes, and consumers can also get a better visual feelings and entertainment experiences with adaptation of various applications to screens with high refresh frequency. A refresh frequency of traditional display devices is generally 60 Hz. In recent years, with developments of technology, display devices with 90 Hz, 120 Hz, 150 Hz and even higher refresh frequency have appeared one after another. From a perspective of panel design, the realization of higher refresh frequency will be affected by factors such as device performance, drive capability, charging rate, etc. For example, during a progressive scan process, a falling edge of a previous scan signal will cause a turn-off delay due to a line load thereof, and display crosstalk resulted from abnormal charging will occur when the progressive scan is faster.

Specifically, when the conventional gate is scanning row by row, a turn-on time of each row is a reciprocal of a refresh frequency. If the refresh frequency is defined as f, the turn-on time of a scan pulse per row is defined as t=1/f. Therefore, when a value of the refresh frequency f is larger, the shorter the turn-on time of each scan pulse. For example, when f is 60 Hz and t is 16.67 ms, and when f is150 Hz and t is 6.67 ms. Since the falling edge of the scan pulse is delayed and the turn-on time of the scan pulse is also shortened with the increase of the refresh frequency, the falling edge of the scan pulse cannot fall to the ideal potential at the end of the turn-on time, resulting in a write transistor in a pixel circuit is still in the on state. That is, the write transistor is still transmitting data signals, which may cause display abnormalities. As shown in FIG. 1, when the next row of sub-pixels is scanned, that is, when a rising edge of the N+1 level scan signal G(N+1) arrives, a potential of the N^{th} level scan signal G(N) still cannot turn off the write transistor in the pixel circuit of the previous line.

Therefore, it is necessary to provide a display panel in which a time required for a falling edge of a scan signal is shorter in a display area, and at the same time, the highest possible aperture ratio can be obtained.

It should be noted that the above-mentioned introduction of the background technology is only for the purpose of facilitating a clear and complete understanding of the technical solutions of the present application. Therefore, it cannot be considered that the above-mentioned technical solutions involved are known to those skilled in the art just because it appears in the background art of the present application.

### SUMMARY OF DISCLOSURE

The present application provides a display panel and a display device to alleviate technical problems that a falling edge of a scan signal in a display area takes a long time and an aperture ratio is low.

In a first aspect, the present application provides a display panel, comprising an active layer, a gate layer and a metal layer. The active layer comprises a source connection area of a pull-down transistor and a drain connection area of the pull-down transistor. The gate layer comprises a gate of the pull-down transistor, a first scan line, and a second scan line, wherein the second scan line is electrically connected to the gate of the pull-down transistor, and the first scan line and the second scan line are sequentially arranged adjacent to each other along the first direction. The metal layer comprises a low potential wiring, a control wiring, a first data line, and a second data line, wherein one end of the control wiring is electrically connected to the source connection area of the pull-down transistor, the other end of the control wiring is electrically connected to the first scan line, the low potential wiring is electrically connected to the drain connection area of the pull-down transistor, and the first data line and the second data line are arranged adjacent to each other in the second direction. Herein, in the second direction, the low potential wiring, the control wiring, and the pull-down transistor are all located between the first data line and the second data line.

In some embodiments, the low potential wiring is close to one of the first data line or the second data line, the control wiring is close to the other one of the first data line or the second data line, and the low potential wiring is a continuous metal pattern in the metal layer.

In some embodiments, the low potential wiring comprises a first wiring portion, the first wiring portion is close to the drain connection area of the pull-down transistor, and the first wiring portion is far away from the first data line or the second data line.

In some embodiments, the control wiring comprises a line turning portion, and the line turning portion extends toward a projection of the source connection area of the pull-down transistor on the metal layer, and the line turning portion at least partially overlaps the projection of the source connection region of the pull-down transistor on the metal layer in a thickness direction of the display panel.

In some embodiments, the projection of the source connection area of the pull-down transistor on the active layer is located on one side of the second scan line and adjacent to the first scan line; and a projection of the drain connection area of the pull-down transistor on the active layer is located on the other side of the second scan line and far away from the first scan line.

In some embodiments, the active layer further comprises a semiconductor structure of a write a transistor, and the semiconductor structure comprises a first linear portion, a second linear portion and a third linear portion patterned and formed integrally; in the thickness direction, a projection of the first linear portion on the metal layer overlaps the first data line, and a projection of the second linear portion on the metal layer at least partially overlaps the line turning portion of the control line, and a projection of the third straight line portion on the metal layer at least partially overlaps the second scan line; and an extension direction of the first linear portion is consistent with an extension direction of the third linear portion, and the first linear portion and the third linear portion are both located on the same side of the second linear portion.

In some embodiments, if the control wiring is adjacent to the first data line, at least a portion of the control wiring is located between the first linear portion and the third linear portion; or if the low potential wiring is adjacent to the first data line, the first wiring portion of the low potential wiring comprises a first wiring portion, a second wiring portion, and a third wiring portion that are integrally patterned and formed; the first wiring portion extends along the second direction, the second wiring portion extends along the first direction, a projection of the second wiring portion in the thickness direction is located between the write transistor and the pull-down transistor; and the third wiring portion extends along the second direction, the third wiring portion and the first wiring portion are both located in the second wiring portion, and a projection of the third wiring portion on the active layer does not overlap with the semiconductor structure.

In some embodiments, the display panel further comprises a first via hole, wherein the first linear portion is electrically connected to the first data line through the first via hole, and a projection of the first via hole in the second direction overlaps the second wiring portion but does not overlap first wiring portion and the third wiring portion.

In some embodiments, the low potential wiring is adjacent to the first data line, and the extension direction of the low potential wiring is correspondingly the same as the extension direction of the first data line; the drain connection area of the pull-down transistor, a channel area of the pull-down transistor, and the source connection area of the pull-down transistor are sequentially arranged along the second direction, and the projection of the low potential wiring on the active layer at least partially overlaps the drain connection area of the pull-down transistor; and the active layer also comprises a semiconductor structure of a write transistor, and the projection of the semiconductor structure on the metal layer is located on one side of the low potential wiring and away from the control wiring in the second direction; and a projection of the semiconductor structure on the metal layer partially overlaps the first data line.

In a second aspect, the present application provides a display device comprising at least one of the above-mentioned display panels, and wherein the low potential wiring is configured to transmit a low potential signal, the first scan line is configured to transmit a first scan signal, and the second scan line is configured to transmit a second scan signal; and a pulse of the first scan line is earlier than a pulse of the second scan signal in the same frame.

In the display panel and the display device provided by the present application, by electrically connecting the second scan line with the gate of the pull-down transistor, one end of the control wiring with the source connection area of the pull-down transistor, the other end of the control wiring with the first scan line, and the low potential wiring and the drain connection area of the pull-down transistor, it is able to quickly pull down a falling edge of a scan signal in a first scan line when a rising edge of a scan signal in a second scan line arrives. At the same time, by constructing the low-potential wiring, the control wiring, and the pull-down transistor between the first data line and the second data line, a layout with less space can be completed and an aperture ratio can be increased as much as possible.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings can be obtained from these accompanying drawings without creative labor.

FIG. 1 is a schematic diagram of a waveform of a scan signal in a conventional technical solution.

FIG. 2 is a schematic diagram of an electrical principle of a display panel provided by an embodiment of the application.

FIG. 3 is a schematic diagram of waveforms of scan signals in the display panel shown in FIG. 2.

FIG. 4 is a schematic cross-sectional structure diagram of a pull-down transistor, a control wiring, a low potential wiring, and a data line provided by an embodiment of the application.

FIG. 5 is a schematic diagram of the first layout design of a display panel provided by an embodiment of the application.

FIG. 6 is a schematic diagram of a second layout design of a display panel provided by an embodiment of the application.

FIG. 7 is a schematic diagram of a third layout design of a display panel provided by an embodiment of the application.

### DETAILED DESCRIPTION

The present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

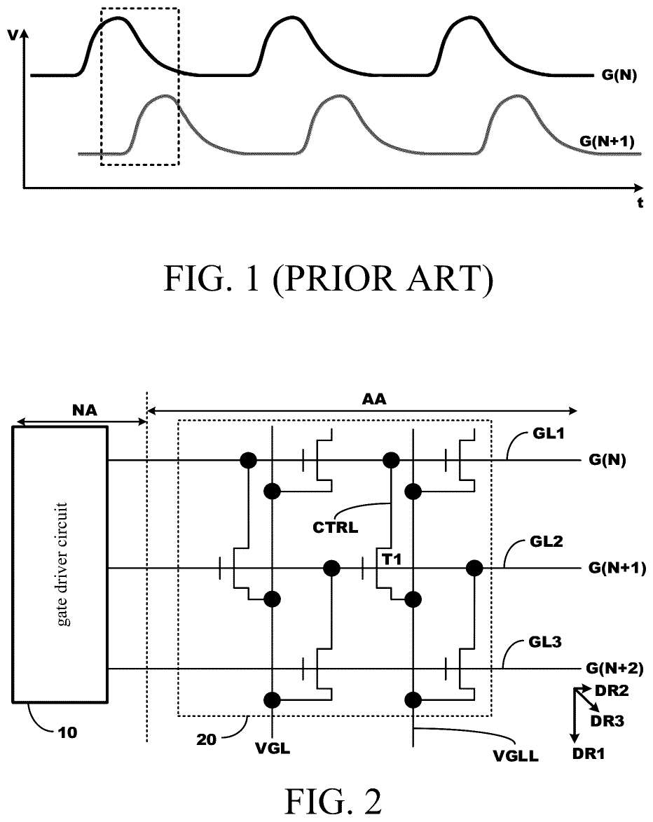

In view of the insufficient time taken by a falling edge of a scan signal in a display area in the traditional technical solution shown in FIG. 1, the present embodiment provides a display panel, please refer to FIG. 2 to FIG. 7. As shown in FIG. 1, the display panel can be divided into a display area AA and a non-display area NA. A gate drive circuit 10 is constructed in the non-display area NA, a plurality of scan lines extend from each output terminal of the gate drive circuit 10 into the display area AA, and these scan lines are arranged in sequence along a first direction DR1. For example, an N^{th} scan line GL1 for transmitting an N^{th} level scan signal G(N), a N+1^{th} scan line GL2 for transmitting the N+1^{th} level scan signal G(N+1), and a N+2^{th} scan line GL3 for transmitting the N+2^{th} level scan signal G(N+2) are arranged in sequence, and a falling edge of the N^{th} level scan signal G(N) can be at the same time or similar to the rising edge of the N+1^{th} level scan signal G(N+1).

A pull-down module 20 is provided in the display area AA. The pull-down module 20 may comprise a plurality of pull-down transistors T1. One of the source or drain of the pull-down transistor T1 can be electrically connected to a low potential wiring VGLL for transmitting a low potential signal VGL, the other of the source or drain of the pull-down transistor T1 can be electrically connected to one end of a control line CTRL, and the other end of the control line CTRL can be electrically connected to the N^{th} scan line GL1, and a gate of the pull-down transistor T1 can be electrically connected to the N+1^{th} scan line GL2. Herein, N can be a positive integer. With the change of N, the pull-down transistor T1 can be distributed in different positions of the display area AA to shorten a time taken by a falling edge of each scan signal in the display area AA.

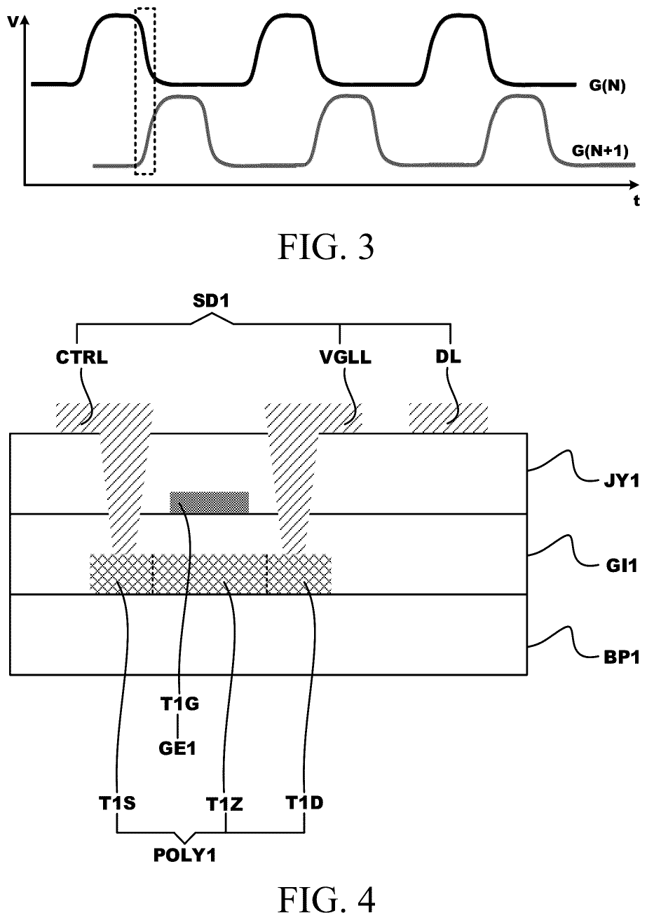

After addition of the pull-down module 20, the time required for the scan signal to change from a high level to a low level can be effectively reduced. For example, compared to FIG. 1, when a rising edge of the N+1 level scan signal G(N+1) shown in FIG. 3 arrives, a falling edge of the N^{th} level scan signal G(N) can be quickly pulled down to a predetermined low potential, which can significantly improve a crosstalk phenomenon of a data signal.

Herein, the pull-down transistor T1 may preferably be an N-channel thin film transistor.

As shown in FIG. 4, the display panel may comprise a substrate BPI, an active layer POLY1, a gate insulating layer GI1, a gate layer GE1, an insulating layer JY1, and a metal layer SD1 that are sequentially stacked in a thickness direction thereof.

Herein, the active layer POLY1 may comprise a source connection area T1S of the pull-down transistor, a channel area T1Z of the pull-down transistor, and a drain connection area T1D of the pull-down transistor.

The gate layer GE1 may comprise a gate T1G of the pull-down transistor.

The metal layer SD1 may comprise a control wiring CTRL, a low potential wiring VGLL, and a data line DL. The control wiring CTRL can be electrically connected to the source connection area T1S of the pull-down transistor, and the low potential wiring VGLL can be electrically connected to of the drain connection area T1D of the pull-down transistor.

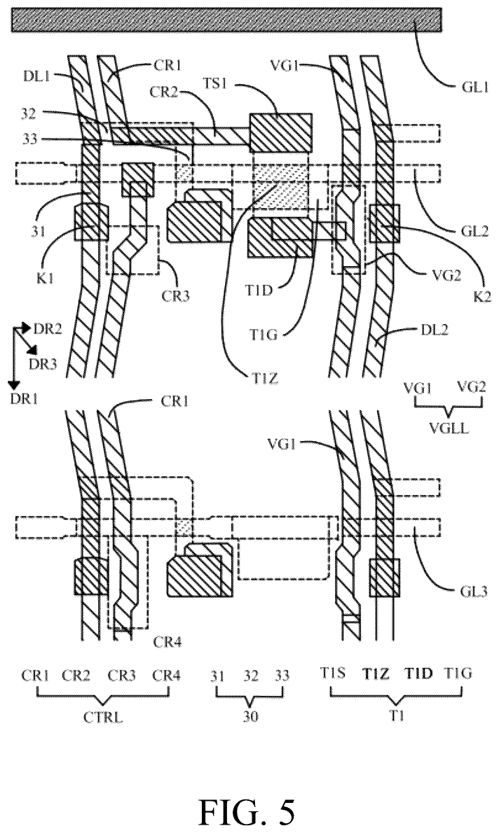

As shown in any one of FIG. 5 to FIG. 7, in one of the embodiments, the first data line DL1 and the second data line DL2 are arranged adjacent to each other in a second direction DR2. In addition, the low potential wiring VGLL, the control wiring CTRL, and the pull-down transistor T1 are all located between the first data line DL1 and the second data line DL2 in the second direction DR2. It is noted that in this way, a layout of newly added structures of the low potential wiring VGLL, the control wiring CTRL, and the pull-down transistor T1 can be completed with less space, and an aperture ratio can be increased as much as possible.

In one of the embodiments, the low potential wiring VGLL is close to one of the first data line DL1 or the second data line DL2, and the control wiring CTRL is close to the other of the first data line DL1 or the second data line DL2. In the metal layer SD1, the low potential wiring VGLL is a continuous metal pattern. It is noted that the use of vias to connect multiple wiring segments to the same low potential wiring VGLL can reduce or avoid by constructing the low potential wiring VGLL in the metal layer SD1 as a continuous metal pattern. That is, wires changing under the black matrix can be reduced or avoided.

Herein, the low potential wiring VGLL may comprise a first trunk portion VG1 and a first wiring portion VG2. The first wiring portion VG2 is close to the drain connection region T1D of the pull-down transistor T1, which can shorten a wiring distance between the first wiring portion VG2 and the drain connection regions T1D of the pull-down transistor T1. The first wiring portion VG2 is far away from the second data line DL2, so that a via hole K2 is arranged at a corresponding position to avoid the short connection between the via hole K2 and the low potential wiring VGLL.

A wiring of the first trunk portion VG1 can be parallel or approximately parallel to a wiring at the corresponding position of the first data line DL1 or the second data line DL2 closing thereof.

In one of the embodiments, the control wiring CTRL may comprise a second trunk portion CR1, a line turning portion CR2, a second wiring portion CR3, and a third wiring portion CR4. The line turning portion CR2 extends toward a projection of the source connection area T1S of the pull-down transistor T1 on the metal layer SD1, and the line turning portion CR2 at least partially overlaps a projection of and the source connection area T1S of the pull-down transistor T1 on the metal layer SD1 in the thickness direction DR3 of the display panel. Therefore, electrical connection between the source connection area T1S of the pull-down transistor T1 and the control wiring CTRL can be implemented under a smallest space.

Herein, the first data line DL1 can be provided with a via K1 at a place corresponding to the second wiring portion CR3 without causing electrical shorting between the control wiring CTRL and the first data line DL1. Similarly, the first data line DL1 may also be provided with a via hole at a place corresponding to the third wiring portion CR4.

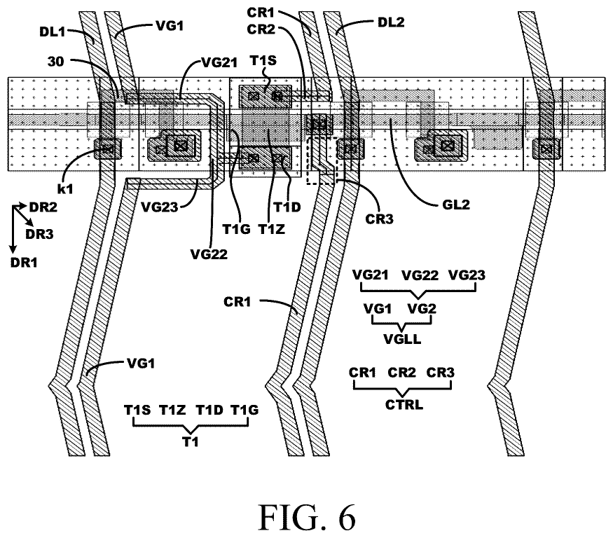

As shown in FIGS. 5 and 6, a projection of the source connection area T1S of the pull-down transistor T1 on the active layer is located on a side of the N+1^{th} scan line GL2 and is close to the N^{th} scan line GL1. A projection of the drain connection region T1D of the pull-down transistor T1 on the active layer is located on the other side of the N+1^{th} scan line GL2 and is far away from the N^{th} scan line GL1 of the first scan line. In this way, the pull-down transistor T1 can be constructed in a narrow space in the second direction DR2.

The active layer may also comprise a semiconductor structure 30 for the write transistor. The semiconductor structure 30 comprises a first linear portion 31, a second linear portion 32, and a third linear portion 33 that are patterned and integrally formed. In a thickness direction DR3, a projection of the linear portion 31 on the metal layer overlaps the first data line DL1, a projection of the second linear portion 32 on the metal layer at least partially overlaps the line turning portion CR2 of the control wiring CTRL, and a projection of the third linear portion 33 on the metal layer at least partially overlaps the N+1^{th} scan line GL2. An extension direction of the first linear portion 31 is consistent with the extension direction of the third linear portion 33, and both the first linear portion 31 and the third linear portion 33 are located on the same side of the second linear portion 32.

As shown in FIG. 5, the control wiring CTRL is close to the first data line DL1, and at least a part of the control wiring CTRL is located between the first linear portion 31 and the third linear portion 33 in the second direction DR2.

As shown in FIG. 6, the low potential wiring VGLL is close to the first data line DL1, and the first wiring portion VG2 of the low potential wiring VGLL comprises a first wiring portion VG21, a second wiring portion VG22 and a third wiring portion VG23 that are patterned and integrally formed. The first wiring portion VG21 extends along the second direction DR2, and the projection of the first wiring portion VG21 on the active layer at least partially overlaps the second linear portion 32, which can reduce the space occupation in the direction DR1. The second wiring portion VG22 extends along the first direction DR1, and the projection of the second wiring portion VG22 in the thickness direction DR3 is located between the write transistor and the pull-down transistor T1. The third wiring portion VG23 extends along the second direction DR2, the third wiring portion VG23 and the first wiring portion VG21 are both located on the same side of the second wiring portion VG22, and the projection of the third wiring portion VG23 on the active layer does not overlap the semiconductor structure 30.

In this way, the write transistor can be configured as a U-shaped thin film transistor, and a distance between the first linear portion 31 and the third linear portion 33 can be increased, so that the second trunk portion CR1 of the control wiring CTRL can pass through the semiconductor structure 30, thereby avoiding lateral overlap with the N+1^{th} scan line GL2 in the first direction DR1, and reducing coupling effects between the thereof and the load of at least one of the two.

As shown in FIGS. 5 and 6, the display panel further comprises a first via K1. The first linear portion 31 is electrically connected to the first data line DL1 through the first via K1, and a projection of the first via K1 in the second on the direction DR2 overlaps the second wiring portion VG22 and does not overlap the first wiring portion VG21 and the third wiring portion VG23. In this way, a part of the semiconductor structure 30 can be placed in the opening of the first wiring portion VG2, and the first via K1 can be dodged to avoid unnecessary electrical shorting.

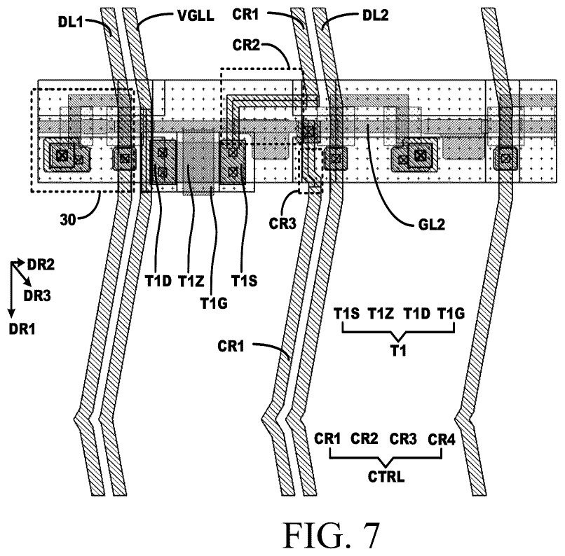

As shown in FIG. 7, in one of the embodiments, the low potential wiring VGLL is close to the first data line DL1, and an extension direction of the low potential wiring VGLL corresponds to the extension direction of the first data line DL1. The drain connection area T1D of the pull-down transistor T1, the channel area T1Z of the pull-down transistor T1, and the source connection area T1S of the pull-down transistor T1 are sequentially arranged along the second direction DR2, and the projection of the low potential wiring VGLL on the active layer at least partially overlaps the drain connection region T1D of the pull-down transistor T1. The active layer also comprises a semiconductor structure 30 for write transistors. In the second direction DR2, the projection of the semiconductor structure 30 on the metal layer is located on a side of the low potential wiring VGLL and is far away from the control Wiring CTRL. The projection of the semiconductor structure 30 on the metal layer partially overlaps the first data line DL1.

It should be noted that, in this embodiment, the semiconductor structure 30 can be arranged on a side of the first data line DL1 away from the second data line DL2, so that the structure of the pull-down transistor T1 in the active layer can be arranged horizontally so as to be parallel with the N+1^{th} scan line GL2. Thus, it is possible to avoid mutual overlap in the thickness direction DR3.

In one of the embodiments, this embodiment provides a display device, comprising a display panel in at least one of the above embodiments. Herein, a low potential wiring is used to transmit low potential signals, and a first scan line is used to transmit the first scan signal, the second scan line is used to transmit the second scan signal. In the same frame, a pulse of the first scan signal is earlier than a pulse of the second scan signal.

It is understandable that in this embodiment, a falling edge of the scan signal in the first scan line can be quickly pulled down when a rising edge of the pulse of the scan signal in the second scan line arrives, which can shorten time spent of the falling edge of the scan signal in the display area. At the same time, new structures such as low potential wirings, control wirings and pull-down transistors are constructed between the first data line and the second data line. A layout can be completed with less space and an aperture ratio can be increased as much as possible.

In the above-mentioned embodiments, the description of each embodiment has its own focus. For parts that are not described in detail in an embodiment, reference can be made to related descriptions of other embodiments.

What is claimed is:

1. A display panel, comprising:
an active layer, comprising a source connection area of a pull-down transistor and a drain connection area of the pull-down transistor;
a gate layer, comprising a gate of the pull-down transistor, a first scan line, and a second scan line, wherein the second scan line is electrically connected to the gate of the pull-down transistor, and the first scan line and the second scan line are sequentially arranged adjacent to each other along the first direction; and
a metal layer, comprising a low potential wiring, a control wiring, a first data line, and a second data line, wherein one end of the control wiring is electrically connected to the source connection area of the pull-down transistor, the other end of the control wiring is electrically connected to the first scan line, the low potential wiring is electrically connected to the drain connection area of the pull-down transistor, and the first data line and the second data line are arranged adjacent to each other in the second direction;
wherein, in the second direction, the low potential wiring, the control wiring, and the pull-down transistor are all located between the first data line and the second data line.

2. The display panel of claim 1, wherein the low potential wiring is close to one of the first data line or the second data line, the control wiring is close to the other one of the first data line or the second data line, and the low potential wiring is a continuous metal pattern in the metal layer.

3. The display panel of claim 2, wherein the low potential wiring comprises a first wiring portion, the first wiring portion is close to the drain connection area of the pull-down transistor, and the first wiring portion is far away from the first data line or the second data line.

4. The display panel of claim 3, wherein the control wiring comprises a line turning portion, and the line turning portion extends toward a projection of the source connection area of the pull-down transistor on the metal layer, and the line turning portion at least partially overlaps the projection of the source connection region of the pull-down transistor on the metal layer in a thickness direction of the display panel.

5. The display panel of claim 1, wherein the projection of the source connection area of the pull-down transistor on the active layer is located on one side of the second scan line and adjacent to the first scan line; and
a projection of the drain connection area of the pull-down transistor on the active layer is located on the other side of the second scan line and far away from the first scan line.

6. The display panel of claim 4, wherein the active layer further comprises a semiconductor structure of a write a transistor, and the semiconductor structure comprises a first linear portion, a second linear portion and a third linear portion patterned and formed integrally;
in the thickness direction, a projection of the first linear portion on the metal layer overlaps the first data line, and a projection of the second linear portion on the metal layer at least partially overlaps the line turning portion of the control line, and a projection of the third straight line portion on the metal layer at least partially overlaps the second scan line; and
an extension direction of the first linear portion is consistent with an extension direction of the third linear portion, and the first linear portion and the third linear portion are both located on the same side of the second linear portion.

7. The display panel of claim 6, wherein if the control wiring is adjacent to the first data line, at least a portion of the control wiring is located between the first linear portion and the third linear portion; or
if the low potential wiring is adjacent to the first data line, the first wiring portion of the low potential wiring comprises a first wiring portion, a second wiring portion, and a third wiring portion that are integrally patterned and formed; the first wiring portion extends along the second direction, the second wiring portion extends along the first direction, a projection of the second wiring portion in the thickness direction is located between the write transistor and the pull-down transistor; and the third wiring portion extends along the second direction, the third wiring portion and the first wiring portion are both located in the second wiring portion, and a projection of the third wiring portion on the active layer does not overlap with the semiconductor structure.

8. The display panel of claim 7, wherein the display panel further comprises:
a first via hole, wherein the first linear portion is electrically connected to the first data line through the first via hole, and a projection of the first via hole in the second direction overlaps the second wiring portion but does not overlap first wiring portion and the third wiring portion.

9. The display panel of claim 2, wherein the low potential wiring is adjacent to the first data line, and the extension direction of the low potential wiring is correspondingly the same as the extension direction of the first data line; the drain connection area of the pull-down transistor, a channel area of the pull-down transistor, and the source connection area of the pull-down transistor are sequentially arranged along the second direction, and the projection of the low potential wiring on the active layer at least partially overlaps the drain connection area of the pull-down transistor; and
the active layer also comprises a semiconductor structure of a write transistor, and the projection of the semiconductor structure on the metal layer is located on one side of the low potential wiring and away from the control wiring in the second direction; and a projection of the semiconductor structure on the metal layer partially overlaps the first data line.

10. A display device, comprising a display panel according to claim 1;
wherein the low potential wiring is configured to transmit a low potential signal, the first scan line is configured to transmit a first scan signal, and the second scan line is configured to transmit a second scan signal; and a pulse of the first scan line is earlier than a pulse of the second scan signal in the same frame.

11. The display device of claim 10, wherein the low potential wiring is close to one of the first data line or the second data line, the control wiring is close to the other one of the first data line or the second data line, and the low potential wiring is a continuous metal pattern in the metal layer.

12. The display device of claim 11, wherein the low potential wiring comprises a first wiring portion, the first wiring portion is close to the drain connection area of the pull-down transistor, and the first wiring portion is far away from the first data line or the second data line.

13. The display device of claim 12, wherein the control wiring comprises a line turning portion, and the line turning portion extends toward a projection of the source connection area of the pull-down transistor on the metal layer, and the line turning portion at least partially overlaps the projection of the source connection region of the pull-down transistor on the metal layer in a thickness direction of the display panel.

14. The display device according to claim 10, wherein the projection of the source connection area of the pull-down transistor on the active layer is located on one side of the second scan line and adjacent to the first scan line; and
a projection of the drain connection area of the pull-down transistor on the active layer is located on the other side of the second scan line and far away from the first scan line.

15. The display device according to claim 13, wherein the active layer further comprises a semiconductor structure of a write a transistor, and the semiconductor structure comprises a first linear portion, a second linear portion and a third linear portion patterned and formed integrally;
in the thickness direction, a projection of the first linear portion on the metal layer overlaps the first data line, and a projection of the second linear portion on the metal layer at least partially overlaps the line turning portion of the control line, and a projection of the third straight line portion on the metal layer at least partially overlaps the second scan line; and
an extension direction of the first linear portion is consistent with an extension direction of the third linear portion, and the first linear portion and the third linear portion are both located on the same side of the second linear portion.

16. The display device of claim 15, wherein if the control wiring is adjacent to the first data line, at least a portion of the control wiring is located between the first linear portion and the third linear portion; or
if the low potential wiring is adjacent to the first data line, the first wiring portion of the low potential wiring comprises a first wiring portion, a second wiring portion, and a third wiring portion that are integrally patterned and formed; the first wiring portion extends along the second direction, the second wiring portion extends along the first direction, a projection of the second wiring portion in the thickness direction is located between the write transistor and the pull-down transistor; and the third wiring portion extends along the second direction, the third wiring portion and the first wiring portion are both located in the second wiring portion, and a projection of the third wiring portion on the active layer does not overlap with the semiconductor structure.

17. The display device of claim 16, wherein the display panel further comprises:
a first via hole, wherein the first linear portion is electrically connected to the first data line through the first via hole, and a projection of the first via hole in the second direction overlaps the second wiring portion but does not overlap first wiring portion and the third wiring portion.

18. The display device of claim 11, wherein the low potential wiring is adjacent to the first data line, and the extension direction of the low potential wiring is correspondingly the same as the extension direction of the first data line; the drain connection area of the pull-down transistor, a channel area of the pull-down transistor, and the source connection area of the pull-down transistor are sequentially arranged along the second direction, and the projection of the low potential wiring on the active layer at least partially overlaps the drain connection area of the pull-down transistor; and
the active layer also comprises a semiconductor structure of a write transistor, and the projection of the semiconductor structure on the metal layer is located on one side of the low potential wiring and away from the control wiring in the second direction; and a projection of the semiconductor structure on the metal layer partially overlaps the first data line.

19. The display device of claim 10, wherein the pulse is a positive pulse.

20. The display device of claim 10, wherein the pull-down transistor is an N-channel type thin film transistor.
